(19) United States
(12) Patent Application Publication
(10) Pub. No.: US 2015/0048301 A1
(43) Pub. Date: Feb. 19, 2015

(54) ENGINEERED SUBSTRATES HAVING MECHANICALLY WEAK STRUCTURES AND ASSOCIATED SYSTEMS AND METHODS

(71) Applicant: Micron Technology, Inc., Boise, ID (US)

(72) Inventors: Oliver J. Kilbury, Boise, ID (US); Martin F. Schubert, Boise, ID (US); Jeremy S. Frei, Boise, ID (US)

(73) Assignee: MICRON TECHNOLOGY, INC., Boise, ID (US)

(21) Appl. No.: 13/970,461

(22) Filed: Aug. 19, 2013

(51) Int. Cl. H01L 21/762; H01L 33/04; H01L 29/06

(52) U.S. Cl. CPC H01L 21/76259; H01L 29/0684; H01L 33/04
USPC 257/13; 438/458; 257/618

(57) ABSTRACT

Engineered substrates having mechanically weak structures for separating substrates from epitaxially grown semiconductor structures and associated systems and methods are disclosed herein. In several embodiments, for example, an engineered substrate can be manufactured by forming an intermediary material at an upper surface of a structural material and forming a plurality of pores in the intermediary material. The porous intermediary material and the structural material can define a handle substrate. The method can further include bonding an epitaxial formation structure on the handle substrate such that the porous intermediary material is between the epitaxial formation structure and the structural material. In various embodiments, the porous intermediary material is configured to break under mechanical stress.

### TECHNICAL FIELD

The present technology is related to engineered substrates having mechanically weak structures and associated systems and methods. In particular, the present technology relates to engineered substrates for separating epitaxially grown semiconductor structures and methods of manufacturing that involve separating semiconductor layers and/or solid state transducers from an engineered substrate.

### BACKGROUND

Solid state lighting (“SSL”) devices are designed to use light emitting diodes (“LEDs”), organic light emitting diodes (“OLEDs”), and/or polymer light emitting diodes (“PLEDs”) as sources of illumination, rather than electrical filaments, plasma, or gas. Solid-state devices, such as LEDs, convert electrical energy to light by applying a bias across oppositely doped materials to generate light from an intervening active region of semiconductor material. SSL devices are incorporated into a wide variety of products and applications including common consumer electronic devices. For example, televisions, mobile phones, tablets, digital cameras, MP3 players, and other portable and non-portable electronic devices utilize SSL devices for backlighting. Additionally, SSL devices are also used for traffic lighting, signage, indoor lighting, outdoor lighting, and other types of general illumination.

Semiconductor layers are often grown on substrates to make solid state transducers, such as LEDs, by epitaxially growing materials on sapphire or other types of growth substrates, such as engineered substrates. FIGS. 1A-1C illustrate a process for forming an SST die where after forming semiconductor materials on a growth substrate, a separate transfer substrate is attached to support the semiconductor materials and the growth substrate is completely removed. FIG. 1A illustrates an SST die 10 formed by growing epitaxial layers, including an N-type gallium nitride (“GaN”) material 12, an active region 14, and a P-type GaN material 16, on a growth substrate 20 to form an SST structure 22. The active region 14 can be a light-emitting indium gallium nitride (“InGaN”) material sandwiched between the N-type and P-type semiconductor materials 12 and 16. The growth substrate 20 is typically sapphire, silicon carbide (“SiC”), silicon, or SiC-on-insulator (SiCOI). The growth substrate 20 can alternatively be an engineered substrate, such as silicon on poly-aluminum nitride.

It is sometimes desirable to remove the growth substrate 20 to improve the optical properties of the SST die 10 or to gain electrical access to the SST structure 22. For example, growth substrates, in particular engineered substrates, are typically opaque and thus will block emission of light produced by the SST structure 22 if the growth substrate 20 is not removed. However, since the epitaxial layers 12, 14, and 16 are extremely delicate and thin (e.g., less than 10 microns), the outer epitaxial layer 16 of the SST die 10 must first be attached to a transfer substrate 24 or die-attach tape before removing the growth substrate 20. As shown in FIG. 1B, the SST structure 22 is sandwiched between the growth substrate 20 and the transfer substrate 24.

FIG. 1C shows the SST die 10 after the growth substrate 20 has been removed in its entirety by conventional processes. For example, lasers, chemical etchants, or grinders are generally used to remove growth substrates from the epitaxial layers. Lasers can deliver photon energy through the growth substrate to heat and decompose (e.g., melt) epitaxial material at the epitaxial/substrate interface to separate the epitaxial material from the substrate. Unfortunately, rapid heating and cooling of the epitaxial material associated with laser lift-off processes can damage the epitaxial material. The damage can include cracking (e.g., crack initiation, crack growth, etc. (and often results in crack propagation across the entire wafer assembly).

Conventional chemical etching lift-off processes often involve exposing the edge of a wafer assembly to a chemical etchant such that the chemical etchant travels toward the center of the wafer assembly through voids formed by a reaction between an epitaxial material and a growth substrate. To separate the epitaxial material from the substrate, the chemical etchant must reach the center of the wafer assembly, which often leads to relatively long etch times. For example, the chemical etchant must travel four inches radially inward along the epitaxial/wafer interface to reach the center of an eight inch diameter wafer assembly. Additionally, it is difficult to consistently deliver the chemical etchant through the voids along the entire epitaxial/growth substrate interface. Grinding processes are often used to mechanically remove substrates from the epitaxial materials as an alternative to chemical etching. Unfortunately, mechanical grinding can damage the epitaxial material and produce relatively large scratches which must be removed by a subsequent polishing process.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. For ease of reference, throughout this disclosure identical reference numbers are used to identify similar or analogous components or features, but the use of the same reference number does not imply that the parts should be construed to be identical. Indeed, in many examples described herein, the identically-numbered parts are distinct in structure and/or function. Furthermore, the same shading may be used to indicate materials in a cross section that can be compositionally similar, but the use of the same shading does not imply that the materials should be construed to be identical.

FIGS. 1A-1C are schematic cross-sectional views of various stages in a method for forming an LED device according to the prior art.

FIGS. 2A-2C are schematic cross-sectional views illustrating portions of a process for forming engineered substrates in accordance with embodiments of the present technology.

FIG. 3 is a cross-sectional view illustrating a portion of a process for forming epitaxially grown semiconductor structures in accordance with further embodiments of the present technology.

FIGS. 4A and 4B are schematic cross-sectional views illustrating portions of a process for separating epitaxially grown semiconductor structures from engineered substrates configured in accordance with another embodiment of the present technology.

FIGS. 5A and 5B are schematic cross-sectional views illustrating portions of a process for separating epitaxially grown semiconductor structures from engineered substrates configured in accordance with a further embodiment of the present technology.

FIG. 6 is a schematic view of an SST system including devices made using an engineered substrate in accordance with the present technology.

### DETAILED DESCRIPTION

Specific details of several embodiments of methods for making semiconductor devices are described herein along with related devices and systems. The term “semiconductor device” generally refers to a solid-state device that includes semiconductor materials. Examples of semiconductor devices include logic devices, memory devices, and diodes, among others. Furthermore, the term “semiconductor device” can refer to a finished device or to an assembly or other structure at various stages of processing before becoming a finished device. Specific details of several embodiments of solid-state transducers (“SSTs”) and associated systems and methods are described below. The term “SST” generally refers to solid-state components that include a semiconductor material as the active medium to convert electrical energy into electromagnetic radiation in the visible, ultraviolet, infrared, and/or other spectra. For example, SSTs include solid-state light emitters (e.g., LEDs, laser diodes, etc.) and/or other sources of emission other than electrical filaments, plasmas, or gases. SSTs can alternately include solid-state components that convert electromagnetic radiation into electricity.

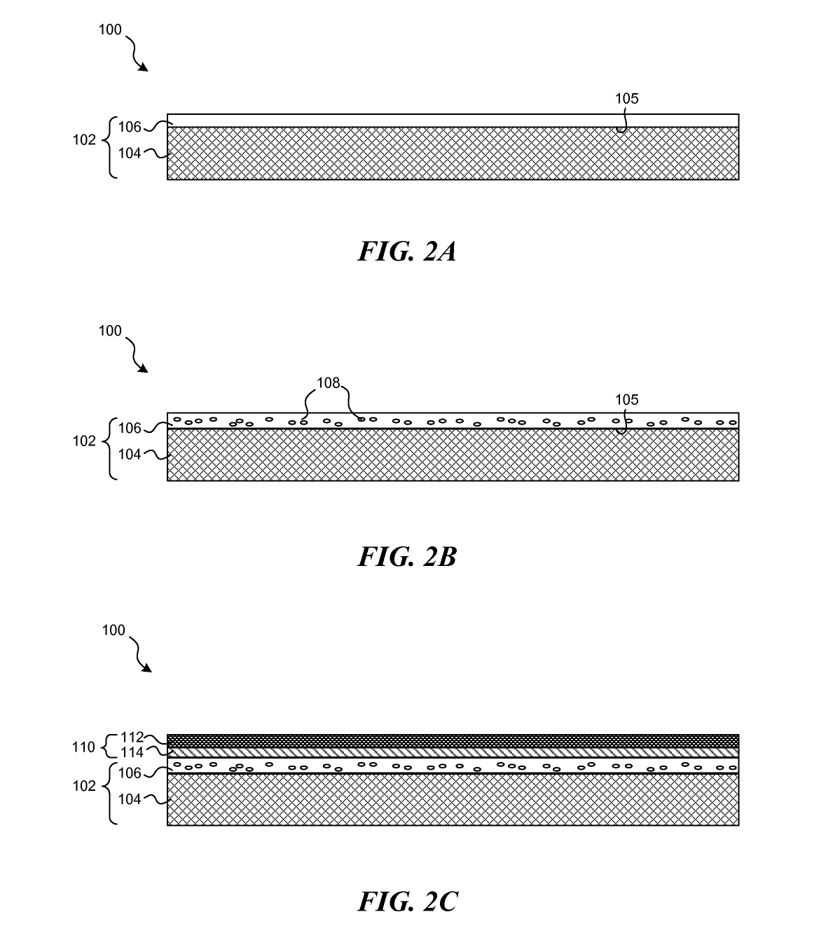

Additionally, depending upon the context in which it is used, the term “substrate” can refer to a wafer-level substrate or to a singulated, die-level substrate. A person having ordinary skill in the relevant art will recognize that suitable steps of the methods described herein can be performed at the wafer-level or at the die-level. Furthermore, unless the context indicates otherwise, structures disclosed herein can be formed using conventional semiconductor-manufacturing techniques. Materials can be deposited, for example, using chemical vapor deposition (CVD), physical vapor deposition (PVD), atomic material deposition (AMD), spin coating, and/or other suitable techniques. Similarly, materials can be removed, for example, using plasma etching, wet etching, chemical-mechanical planarization (CMP), or other suitable techniques. Further, features can be formed in structures, for example, by forming a patterned mask (e.g., a photoresist mask or a hard mask) on one or more semiconductor materials and depositing materials or removing materials in combination with the patterned mask. A person skilled in the relevant art will also understand that the technology may have additional embodiments, and that the technology may be practiced without several of the details of the embodiments described below with reference to FIGS. 2A-6.

As discussed above in the background section, previous lift-off methods to remove the growth substrate from the semiconductor materials have relied on chemical etching which can be time and capital expensive and in not feasible in manufacturing settings. Also as discussed above, mechanical grinding processes can cause damage to the semiconductor layers and prohibit reuse of the growth substrates which increases manufacturing costs. In manufacturing a conventional semiconductor device, the substrate that provides a support surface for epitaxial growth of semiconductor layers or films and is used to form or “grow” the device is commonly referred to as a “handle” substrate. Because of the disadvantages illustrated above, the handle substrate is typically not removed because removal requires additional processing steps that complicate manufacturing and increase manufacturing costs. Rather, the handle substrate is singulated along with the other semiconductor materials to form the semiconductor device.

Methods and devices in accordance with embodiments of the present technology, however, can provide several advantages over these and other manufacturing techniques. A method can include, for example, providing a mechanically weak intermediary material (e.g., a sacrificial material) located between a semiconductor structure and a structural material or substrate to provide means for separating or isolating the semiconductor structure from the handle substrate. In some embodiments, the mechanically weak intermediary material can be compromised, broken or fractured to decouple the semiconductor structure from the handle substrate.

In general, the intermediary material can include a porous film or layer that can withstand processing in epitaxial chamber conditions, but will break when mechanical stress is induced or otherwise applied (e.g., during epitaxial transfer). In one embodiment, the intermediary material can be CVD or PVD polycrystalline Si that is wet etched to create pores (e.g., with desired pore diameters). In another embodiment, the mechanically weak intermediary material can be an inherently non-conformal film epitaxially grown on the handle substrate. During epitaxial transfer and removal of the handle substrate from the semiconductor structure, applied mechanical stress can compromise and cause a break or fissure in the intermediary material without damaging the semiconductor structure or the handle substrate.

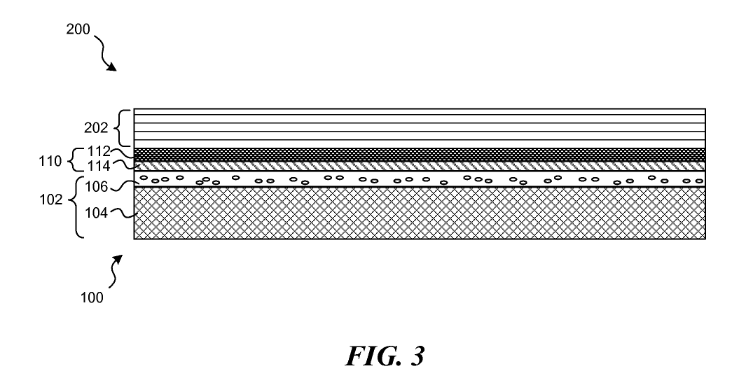

FIGS. 2A-2C are cross-sectional side views illustrating a process for forming an engineered substrate assembly 100 in accordance with the present technology, and FIG. 3 is a cross-sectional side view illustrating epitaxially grown semiconductor layers and/or SSTs on the engineered substrate assembly 100 of FIG. 2C in accordance with another embodiment of the present technology.

FIG. 2A illustrates a stage in a process of forming a handle substrate 102 having a supportive structural material 104 and after an intermediary material 106 (e.g., a sacrificial material) has been formed on an upper surface 105 of the structural material 104. The structural material 104 can be made from an insulating material (e.g., ceramic, glass, etc.) and/or other suitable substrate materials (e.g., insulating or non-insulating materials, silicon, etc.). In certain embodiments, the structural material 104 may include a polycrystalline ceramic material that has a coefficient of thermal expansion (CTE) substantially similar to the CTE of N-type gallium nitride (GaN) and/or other III-nitrides to reduce thermal stress during epitaxial growth of III-nitrides. In one embodiment, the structural material 104 is poly-aluminum nitride (P-AlN). The structural material 104 may also include, for example, compositions of Si₃N₄, TiN, ZrN, HfN, SiO₂, Al₂O₃, AlON, TiC, ZrC, HfC, SiC, Y₂O₃ and/or other suitable polycrystalline ceramics.

The intermediary material 106 is a sacrificial material that can be broken or compromised under mechanical stress, for example, to facilitate the separation of the structural material 104 from a semiconductor structure (not shown). For example, the intermediary material 106 can include a deposited silicon (Si) material and/or a polycrystalline Si. In some embodiments, the Si material can be a CVD or PVD deposited material which can be etched (e.g., electrochemically, photoelectrochemically, etc.) to create pores with desired diameters (e.g., approximately less than 1 μm) to make the intermediary material 106 mechanically weakened compared to other materials used to form the handle substrate 102 (e.g., the structural material 104). In other embodiments, however, the intermediary material 106 can be composed of a material deposited in a manner that would inherently form or otherwise have suitable pores.

FIG. 2B illustrates a stage in the process of forming the handle substrate 102 after the intermediary material 106 has been electrochemically etched to create pores 108 distributed throughout the material. In one particular embodiment, the intermediary material 106 can be an Si material and tetraethyl orthosilicate (TEOS) can be used to etch the Si intermediary material 106 to produce the pores 108 of the desired diameter. The intermediary material 106 can also include a different material in addition to or in lieu of an Si material. For example, the intermediary material 106 may include a nitride-based or oxide-based material. The mechanical weakness of the intermediary material 106 may vary depending upon the type of intermediary material, the deposition method, and the amount and/or the size of the pores 108 in the intermediary material 106. Accordingly, in various embodiments the material, the deposition method and/or the etch method can be optimized to obtain a desired mechanical weakness of the intermediary material 106. In other embodiments, the pressure, power, gas flow rate, magnetic strength, and/or other deposition parameters as well as the etch rate, time and etchant can be selected based on the desired properties of the mechanically weak intermediary material 106.

FIG. 2C shows a later stage in the process after which an epitaxial formation structure 110 has been bonded to the handle substrate 102. The epitaxial formation structure 110 can include an epitaxial seed material 112 for facilitating epitaxial growth of semiconductor materials and a bonding material 114 for bonding the seed material 112 to the handle substrate via oxide-oxide bonding or other suitable bonding techniques (e.g., hydrogen bonds, other chemical bonds, etc.) and/or adhesives. The epitaxial formation structure 110 can be formed by conventional processes (not shown) that include providing a donor substrate (not shown) that includes material that facilitates epitaxial growth of III-nitride structures (e.g., an LED structure). For example, the donor substrate can include Si, at least a portion of which has an Si (1,1,1) crystal orientation (or other suitable materials that facilitate epitaxial growth), and which is subsequently exfoliated by known processes to leave the remaining seed material 112.

The bonding material 114 can comprise materials that grow native oxides (e.g., amorphous polymers, amorphous silicon, oxides, etc.). In one particular example, the bonding material 114 can include an oxide of silicon, such as silicon dioxide (SiO₂). The bonding material 114 can be formed on the donor substrate using PVD, CVD, ALD, spin on coating and/or other suitable formation methods. The bonding material 114 may undergo an additional polishing step (e.g., using chemical-mechanical polishing (“CMP”)) to thin the bonding material 114 and to form a substantially smooth surface and/or to reduce a thickness of the bonding material 114 to about 250-350 Å (e.g., 300 Å). Accordingly, conventional bonding of the donor substrate to the handle substrate 102 via the bonding material 114 followed by exfoliation and optional CMP polishing can produce the engineered substrate assembly 100 shown in FIG. 2C. One of ordinary skill in the art will recognize additional or different steps for forming a suitable epitaxial formation structure 110 on the handle substrate 102 (e.g., on a surface of the intermediary material 106).

FIG. 3 is a cross-sectional view illustrating a further portion of a process for forming a semiconductor assembly 200 on the engineered substrate assembly 100 of FIG. 2C in accordance with further embodiments of the present technology. For example, FIG. 3 shows the engineered substrate assembly 100 of FIG. 2C following the formation of an epitaxially grown semiconductor structure 202 on the epitaxial formation structure 110 (e.g., in an epitaxy process chamber). The engineered substrate assembly 100 (FIG. 2C) can facilitate epitaxial growth of the semiconductor structure 202. For example, the handle substrate 102 can mechanically support the semiconductor structure 202 during manufacturing, while the epitaxial formation structure 110, and specifically the epitaxial seed material 112, provides a growth surface such as a crystalline template to facilitate epitaxial growth of the semiconductor material(s) of the semiconductor structure 202. In the assembly 200, the mechanically weak intermediary material 106 is between the semiconductor structure 202 and the handle substrate 102. As discussed above, the intermediary material 106 is a sacrificial material that can be broken or compromised under mechanical stress to facilitate the separation of the handle substrate 102 from the semiconductor structure 202 without extensive etching, grinding or laser processing.

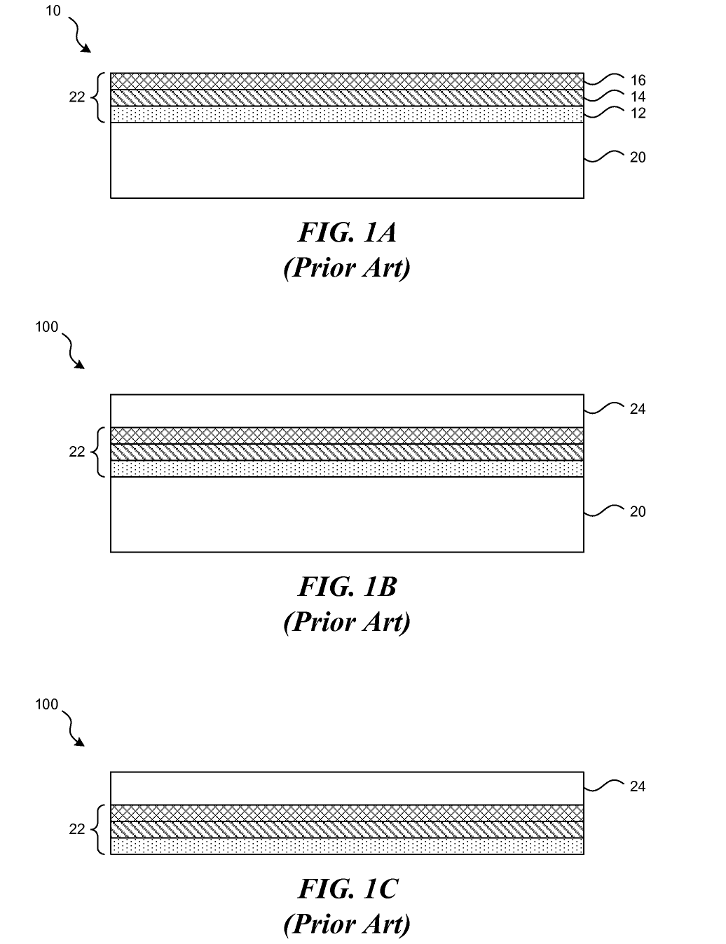

The semiconductor structure 202 can have a plurality of dies or other structures that include integrated circuitry or other types of semiconductor devices. As such, the semiconductor structure 202 can include a single semiconductor material, a stack of different semiconductor materials, and/or other suitable materials. In a particular example, the semiconductor structure 202 can include epitaxial layers, such as those layers described with reference in FIG. 1A. For example, the semiconductor structure 202 may include a first semiconductor material (e.g., an N-type GaN material), an active region (e.g., containing a light-emitting InGaN), and a second semiconductor material (e.g., P-type GaN material) formed sequentially on the epitaxial formation structure 110. In selected embodiments, the first and second semiconductor materials 332 and 336 can individually include at least one of gallium arsenide (GaAs), aluminum gallium arsenide (AlGaAs), gallium arsenide phosphide (GaAsP), gallium (III) phosphide (GaP), zinc selenide (ZnSe), boron nitride (BN), aluminum gallium nitride (AlGaN), and/or other suitable semiconductor materials. Additionally, the active region can include at least one of a bulk indium gallium nitride (InGaN), an InGaN single quantum well, and Gan/InGaN multiple quantum wells. The semiconductor structure 202 can be configured to emit light in the visible spectrum (e.g., from about 390 nm to about 750 nm), in the infrared spectrum (e.g., from about 1050 nm to about 1550 nm), and/or in other suitable spectra.

The semiconductor structure 202 can be formed via metal organic chemical vapor deposition (“MOCVD”), molecular beam epitaxy (“MBE”), liquid phase epitaxy (“LPE”), hydride vapor phase epitaxy (“HVPE”), and/or other suitable epitaxial growth techniques. In other embodiments, the semiconductor structure 202 can also include other suitable components, such as a buffer material that facilitates the formation of semiconductor materials and the active region (not shown individually) on the epitaxial formation structure 110. In further embodiments, the semiconductor structure 202 can include additional bonding and seed layers to facilitate bonding and/or epitaxial growth.

Although omitted for purposes of clarity, a person having ordinary skill in the art will appreciate that the semiconductor structure 202 can include a variety of materials. For example, in addition to materials that are semiconductive, the semiconductor structure 202 can include conductive materials (e.g., metallic materials) and insulative materials (e.g., dielectric materials). Also, the semiconductor structure 202 can include a variety of features formed throughout the structure. For example, the semiconductor structure 202 can include a through-substrate interconnect (not shown) that extends through the semiconductor structure 202. Such a through-substrate interconnect can electrically connect opposite sides of a finished semiconductor device, for example.

Once formed, the semiconductor structure 202 can be integrated into an SST device. For example, the method can further include forming other features of an SST device, such as forming a lens over the semiconductor structure 202, a mirror on a back side of the semiconductor structure 202, electrical contacts on or in the semiconductor structure 202, and/or other suitable mechanical/electrical components (not shown). In various embodiments, the semiconductor structure 202 can be removed from the engineered substrate assembly 100 before being integrated into an SST device. In further embodiments, the structural material 104 can be used in subsequent processes. For example, the structural material 104 can be used to grow additional structures (e.g., semiconductor structures 202 such as LEDs, transducers, etc.) to reduce fabrication costs.

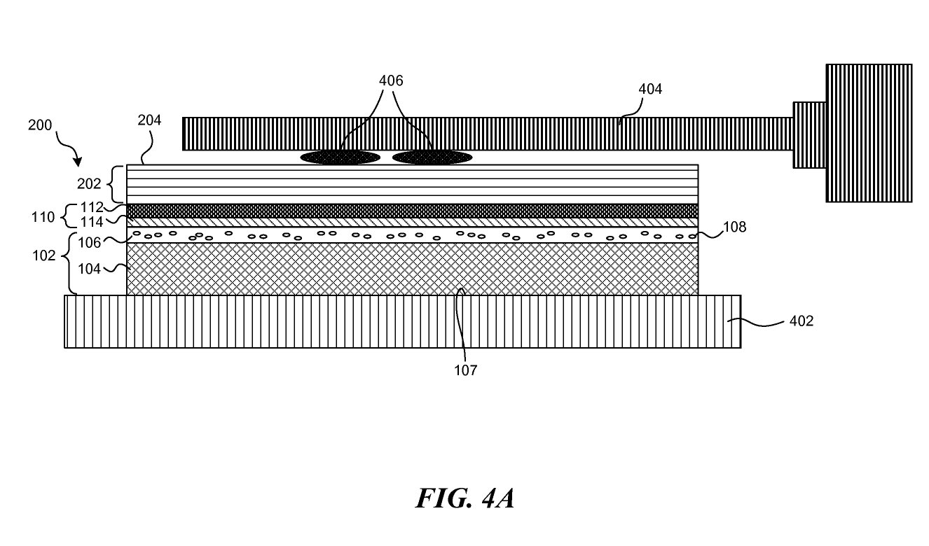

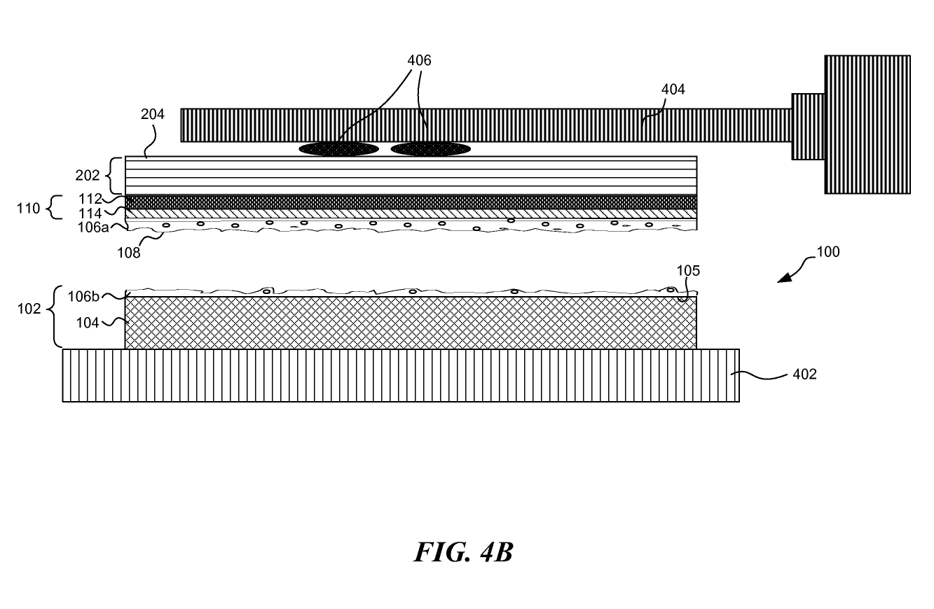

FIGS. 4A and 4B are schematic cross-sectional views illustrating portions of a process for separating the epitaxially grown semiconductor structure 202 from the handle substrate 102 configured in accordance with another embodiment of the present technology. The separation process illustrated in FIGS. 4A and 4B demonstrates fracture or breakage of the mechanical weak intermediary material 106 using mechanical energy. The separation of the semiconductor structure 202 from the handle substrate 102 can occur in a chamber having a lower assembly 402 (e.g., a wafer chuck or stationary chuck) and an upper assembly 404 (e.g., a wafer chuck with rotational movement and/or ultrasound energy delivery capabilities) spaced apart from the lower assembly 402 (e.g., above the semiconductor assembly 200).

As shown in FIG. 4A, one or more transfer structures 406 can be at least temporarily attached to an upper surface 204 of the semiconductor structure 202. For example, the transfer structures 406 can include an adhesive (not shown) for at least temporarily binding the semiconductor structure 202 with the transfer structures 406. A lower surface 107 of the handle substrate 102 can be at least temporarily held or attached (e.g., via adhesive) to the lower assembly 402, while the transfer structures 406 can be at least temporarily coupled to the upper surface 204 of the semiconductor assembly 200 and to the upper assembly 404. In some embodiments, the upper assembly 404 can provide lateral rotation, vibratory motion or other motion for preferentially causing deformation of the mechanically weak (e.g., porous) intermediary material 106. In other embodiments, the upper assembly 404 can apply ultra-sonic energy or vibration to the semiconductor assembly 200 to induce microfractures between pores 108 in the intermediary material 106.

As shown in FIG. 4B, mechanical deformation of the intermediary material 106 can cause the material 106 to crack and separate from the handle substrate 102. One of ordinary skill in the art will recognize other suitable mechanisms for applying mechanical or ultrasound energy to the semiconductor assembly for mechanically breaking down and/or weakening the intermediary material 106. For example, the mechanically weakened or fractured intermediary material 106 can be broken apart along one or more fracture lines to result in intermediary material portions 106a and 106b adhered to the epitaxial formation structure 110 and the structural material 104, respectively.

Following separation of the semiconductor structure 202 from the handle substrate 102, the remaining intermediary material portions 106a and 106b can be removed via polishing (e.g., CMP), grinding, chemical etching, or other suitable method for removing the intermediary material. For example, the intermediary portions 106a and 106b can be removed via etching media selected based on desired etching rates and the type of etching process (e.g., wet etching, vapor etching, dry etching, etc.). The etching media can be a liquid suitable for wet etching (e.g., a liquid containing hydrofluoric acid, buffers, additives, etc.), or a vapor (e.g., vapor hydrofluoric acid). The etching media can selectively etch the intermediary portions 106a and 106b without etching the structural material 104 or any portions of the semiconductor structure 202. Once the intermediary portion 106b is removed via wet, dry or vapor etch for example, the structural material 104 can be used to grow further semiconductor structures 202. For example, an additional mechanically weak intermediary material 106 can be formed on the upper surface 105 of the structural material 104 to form the handle substrate 102. In other embodiments, the structural material 104 can accommodate additional or other materials to form an alternative type of engineered substrate assembly 100 suitable for epitaxy of semiconductor structures 202.

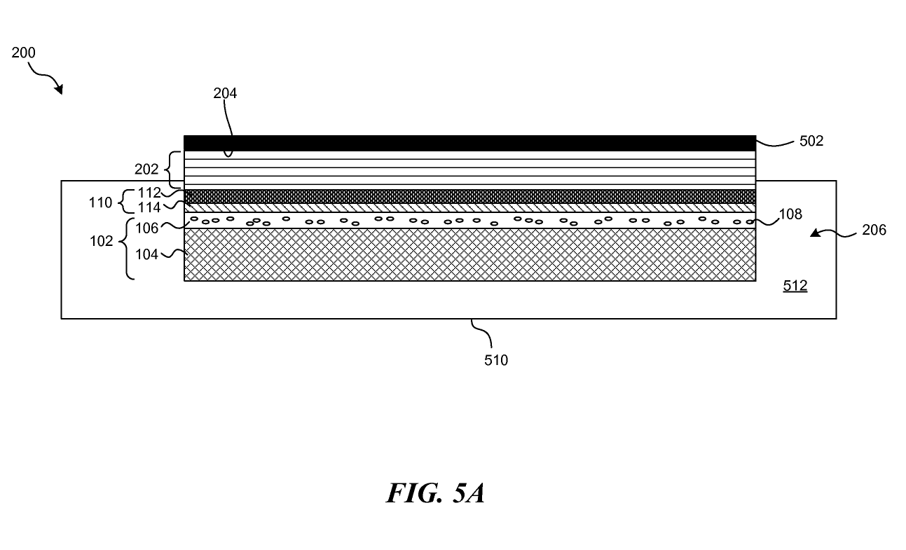

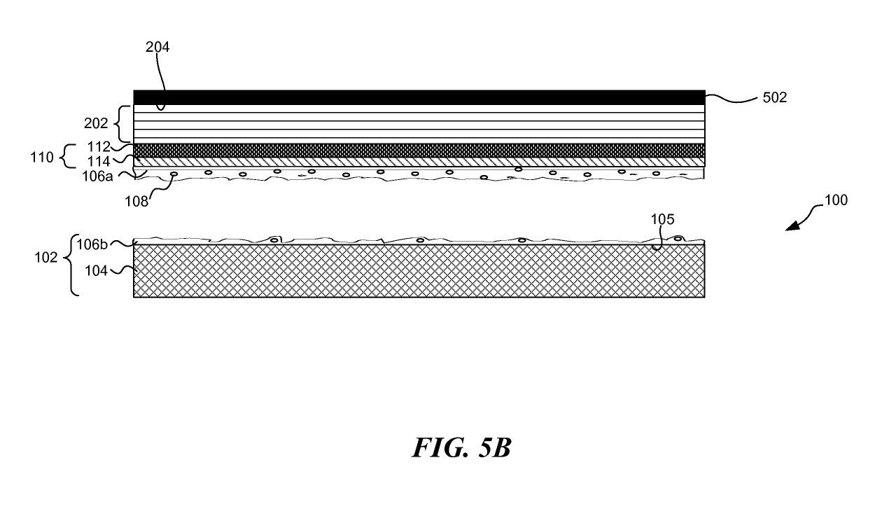

FIGS. 5A and 5B are schematic cross-sectional views illustrating portions of another process for separating the epitaxially grown semiconductor structure 202 from the handle substrate 102 configured in accordance with a further embodiment of the present technology. The separation process illustrated in FIGS. 5A and 5B demonstrates fracture or breakage of the mechanical weak intermediary material 106 using temperature-induced liquid expansion (e.g., formation of crystalline structures, ice formation, etc.) within the pores 108 of the intermediary material 106. For example, and in a particular embodiment, FIG. 5A shows the semiconductor assembly 200 after a transfer structure 502 is at least temporarily attached to the upper surface 204 of the semiconductor structure 202. In one embodiment, the transfer structure 502 can be a transfer tape temporarily adhered to the upper surface 204. In another embodiment the transfer structure 502 can be a transfer wafer and include an adhesive (not shown) for at least temporarily binding the semiconductor structure 202 to the transfer structure 502. As shown in FIG. 5A, all or a lower portion 206 of the semiconductor assembly 200 can be temporarily submerged in an aqueous bath 510 (e.g., liquid water bath). In the bath 510, the liquid 512 (e.g., water) is absorbed and retained in the pores 108 of the intermediary material 106. Subsequent transfer of the semiconductor assembly 200 to a cold chamber (not shown) causes the liquid 512 to freeze and expand within the pores 108 thereby causing the porous intermediary material 106 to break (shown in FIG. 5B). Aspects of the process illustrated in FIGS. 5A-B can be advantageous because elevated temperatures, such as temperatures that could cause stress or cracking of semiconductor materials (e.g., GaN), can be avoided.

Once released, the handle substrate 102 having the structural material 104 and the intermediary material portion 106b can be etched (e.g., wet, dry, vapor, etc.) to remove the remaining intermediary material 106 left adhered to the upper surface 105 of the structural material 104. The structural material 104 can then be recycled and used to form other semiconductor structures as described above. Alternatively, the recovered structural material 104 can be discarded depending on the life-cycle of the structural material 104. For example, the structural material 104 (or handle substrate 102 with remaining intermediary material portion 106b) can be discarded if it has become too thin, contaminated, and/or cycled more than a pre-determined number of times.

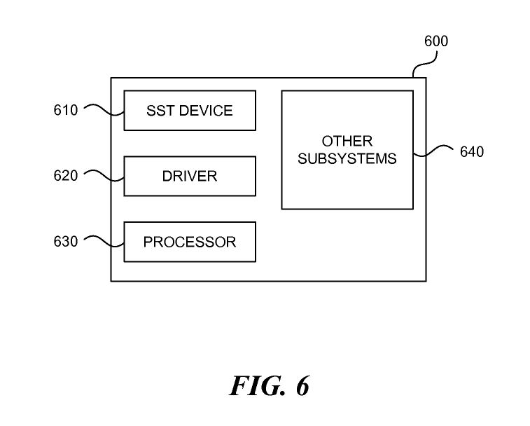

The substrate assemblies and semiconductor devices described above with reference to FIGS. 2A-5B can be used to form SST devices, SST structures, and/or other semiconductor structures that are incorporated into any of a myriad of larger and/or more complex devices or systems, a representative example of which is system 600 shown schematically in FIG. 6. The system 600 can include one or more semiconductor/SST devices 610, a driver 620, a processor 630, and/or other subsystems or components 640. The resulting system 600 can perform any of a wide variety of functions, such as backlighting, general illumination, power generations, sensors, and/or other suitable functions. Accordingly, representative systems can include, without limitation, hand-held devices (e.g., mobile phones, tablets, digital readers, and digital audio players), lasers, photovoltaic cells, remote controls, computers, and appliances. Components of the system 600 may be housed in a single unit or distributed over multiple, interconnected units (e.g., through a communications network). The components of the system 600 can also include local and/or remote memory storage devices, and any of a wide variety of computer readable media.

From the foregoing, it will be appreciated that specific embodiments of the disclosure have been described herein for purposes of illustration, but that various modifications may be made without deviating from the disclosure. For example, the engineered substrate assembly 100 shown in FIG. 2C includes a mechanical weak intermediary material 106 between and directly adjacent to the structural material 104 and the bonding material 114. However, in other embodiments, the engineered substrate assembly 100 in accordance with the present technology can include additional layers of materials between the intermediary material 106 and the bonding material 114 and/or structural material 104. In addition, certain aspects of the disclosure described in the context of particular embodiments may be combined or eliminated in other embodiments. Further, while advantages associated with certain embodiments have been described in the context of those embodiments, other embodiments may also exhibit such advantages. Not all embodiments need necessarily exhibit such advantages to fall within the scope of the present disclosure. Accordingly, the disclosure and associated technology can encompass other embodiments not expressly shown or described herein.

I/We claim:

1. A method of forming an engineered substrate, comprising:
forming a handle substrate having a structural material and an intermediary material at an upper surface of the structural material, wherein the intermediary material has a plurality of pores; and
bonding an epitaxial formation structure on the handle substrate, wherein the porous intermediary material is between the epitaxial formation structure and the structural material, and wherein the porous intermediary material is configured to break under mechanical stress.

2. The method of claim 1 wherein:
the intermediary material is formed at the upper surface of the structural material by depositing a silicon material on the upper surface of the structural material, the structural material comprising a polycrystalline ceramic material; and
the plurality of pores are formed in the intermediary material by wet etching the intermediary material to form the pores.

3. The method of claim 1 wherein bonding an epitaxial formation structure on the handle substrate includes providing an epitaxial seed material for facilitating epitaxial growth of semiconductor materials and a bonding material for bonding the seed material to the handle substrate.

4. The method of claim 1 wherein the intermediary material at the upper surface of the structural material is formed by depositing a polycrystalline silicone material.

5. The method of claim 1 wherein the plurality of pores in the intermediary material is formed having a diameter approximately less than 1 μm.

6. The method of claim 1 wherein the plurality of pores in the intermediary material is formed by wet etching the intermediary material with tetraethyl orthosilicate.

7. The method of claim 1 wherein the intermediary material is formed at the upper surface of the structural material by chemical vapor deposition of silicon material.

8. The method of claim 1 wherein the intermediary material at an upper surface of a structural material includes physical vapor deposition of silicone material.

9. The method of claim 1 wherein bonding an epitaxial formation structure on the handle substrate includes forming oxide-oxide bonds between a donor substrate and the intermediary material via a bonding material.

10. The method of claim 9, further comprising separating the epitaxial formation structure from the donor substrate via exfoliation.

11. A method of forming a solid state transducer (SST) assembly, comprising:
forming an engineered substrate by—
depositing an intermediary material on an upper surface of a structural material, wherein the intermediary material and the structural material define a handle substrate;
forming a plurality of pores in the intermediary material and thereby mechanically weaken the intermediary material;
transferring an epitaxial formation structure from a donor substrate to a surface of the handle substrate, wherein the intermediary material is between the epitaxial formation structure and the structural material; and
epitaxially growing semiconductor material on the epitaxial formation structure for forming a semiconductor structure on the handle substrate.

12. The method of claim 11, further comprising separating the semiconductor structure from the handle substrate by breaking the intermediary material.

13. The method of claim 12 wherein breaking the intermediary material includes delivering ultrasound energy to the intermediary material.

14. The method of claim 12 wherein breaking the intermediary material includes applying force to the semiconductor structure and thereby moving the semiconductor structure relative to the handle substrate.

15. The method of claim 12 wherein breaking the intermediary material includes forming ice in the pores of the intermediary material.

16. The method of claim 15 wherein forming ice in the pores includes submerging at least the handle substrate in a liquid bath and transferring the SST assembly to a cold chamber.

17. The method of claim 11, further comprising attaching a moving assembly to an upper surface of the semiconductor structure and attaching a stationary assembly to the handle substrate, and wherein the moving assembly can move relative to the stationary assembly and thereby mechanically deform the intermediary material.

18. The method of claim 11 wherein depositing an intermediary material on an upper surface of a structural material includes depositing a silicon material on a polycrystalline aluminum nitride material.

19. The method of claim 11 wherein forming a plurality of pores in the intermediary material includes etching the intermediary material with liquid tetraethyl orthosilicate.

20. The method of claim 11 wherein the individual pores each of a diameter of approximately 1 μm or less.

21. The method of claim 11 wherein epitaxially growing semiconductor material on the epitaxial formation structure comprises:
forming an N-type gallium nitride (GaN) on the epitaxial formation structure;
forming an active region on the N-type GaN, the active region comprising at least one of a bulk indium gallium nitride (InGaN), an InGaN single quantum well, and Gan/InGaN multiple quantum wells; and
forming a P-type GaN on the active region.

22. An engineered substrate assembly, comprising:
a structural material;
an intermediary material on the structural material, wherein the intermediary material has a plurality of pores, and wherein the intermediary material is configured to break when mechanically stressed; and
an epitaxial formation structure on the intermediary material such that the intermediary material is between the structural material and the epitaxial formation structure.

23. The engineered substrate assembly of claim 22 wherein:
the structural material comprises a polycrystalline ceramic;
the intermediary material comprises a silicon material having pores with diameters of approximately less than 1 μm; and
the epitaxial formation structure comprises a silicon seed material having a Si(1,1,1) crystal orientation and a bonding material between the seed material and the intermediary material.

24. The engineered substrate assembly of claim 22 wherein the structural material comprises poly-aluminum nitride.

25. The engineered substrate assembly of claim 22 wherein the intermediary material is a sacrificial material that can be broken or compromised under mechanical stress.

26. The engineered substrate assembly of claim 22 wherein the intermediary material includes polycrystalline silicon.

27. A semiconductor assembly, comprising:
an engineered substrate including a structural material, an intermediary material on the structural material, and an epitaxial formation structure on the intermediary material, wherein the intermediary material comprises porous silicon configured to preferentially break under mechanical stress; and
a semiconductor structure on the epitaxial formation structure.

28. The semiconductor assembly of claim 27 wherein the semiconductor structure is a light emitting diode (LED) device.

29. The semiconductor assembly of claim 27 wherein the intermediary material includes a plurality of individual pores having approximately less than a 1 μm diameter.

30. The semiconductor assembly of claim 27 wherein the structural material is a polycrystalline ceramic having a coefficient of thermal expansion (CTE) substantially similar to a CTE of gallium nitride (GaN).

31. The semiconductor assembly of claim 27 wherein the epitaxial formation structure is bonded to the intermediary material, and wherein the epitaxial formation structure comprises silicon having a Si (1,1,1) crystal orientation.

32. The semiconductor assembly of claim 27 wherein the semiconductor structure comprises:
a first semiconductor material formed on the epitaxial formation structure, the first semiconductor material comprising N-type gallium nitride (GaN),
an active region on the first semiconductor material, the active region comprising at least one of a bulk indium gallium nitride (InGaN), an InGaN single quantum well, and Gan/InGaN multiple quantum wells, and
a second semiconductor material the active region, the second semiconductor material comprising P-type GaN.

33. A light-emitting diode (LED) structure, comprising:
a first semiconductor material formed on an epitaxial formation structure, the first semiconductor material comprising N-type gallium nitride (GaN),
an active region on the first semiconductor material, the active region comprising at least one of a bulk indium gallium nitride (InGaN), an InGaN single quantum well, and Gan/InGaN multiple quantum wells, and
a second semiconductor material the active region, the second semiconductor material comprising P-type GaN;
wherein the epitaxial formation structure is bonded to an engineered substrate via an intermediary material; and
wherein the intermediary material has a plurality of pores and is configured to preferentially break under mechanical stress.

34. The LED structure of claim 33 wherein the intermediary material comprises porous silicon.

35. The LED structure of claim 33 wherein:
the engineered substrate comprises a polycrystalline ceramic material;
the intermediary material comprises a silicon material having pores with diameters of approximately less than 1 μm; and
the epitaxial formation structure comprises a silicon seed material having a Si(1,1,1) crystal orientation and a bonding material between the seed material and the intermediary material.
